(19) United States
(12) Patent Application Publication
(10) Pub. No.: US 2025/0135591 A1
(43) Pub. Date: May 1, 2025

(54) SPIN CHUCK AND SUBSTRATE PROCESSING APPARATUS INCLUDING THE SAME

(71) Applicant: SAMSUNG ELECTRONICS CO., LTD., Suwon-si (KR)

(72) Inventors: Hyunchul KIM, Suwon-si (KR); Ohchel KWON, Suwon-si (KR); Daewoong CHOI, Suwon-si (KR); Hyunmo KANG, Suwon-si (KR); Jinhong PARK, Suwon-si (KR); Wooseok CHOE, Suwon-si (KR)

(73) Assignee: SAMSUNG ELECTRONICS CO., LTD., Suwon-si (KR)

(21) Appl. No.: 18/927,195

(22) Filed: Oct. 25, 2024

(30) Foreign Application Priority Data
Oct. 27, 2023 (KR) 10-2023-0145965

(51) Int. Cl. B23Q 3/08; B23Q 3/06

(52) U.S. Cl. CPC B23Q 3/084; B23Q 3/062

(57) ABSTRACT

A spin chuck includes an upper plate having an upper surface and a lower surface, the upper plate including a groove and a support pin on the upper surface of the upper plate, wherein the support pin is configured to support a substrate; an anti-slip plate below the upper plate, the anti-slip plate having an upper surface and a lower surface, wherein the anti-slip plate includes a first protrusion protruding in a vertical direction from the upper surface of the anti-slip plate toward the upper plate; and a lower plate below the anti-slip plate, the lower plate including a chucking pin configured to fix the substrate, wherein the lower plate has an upper surface and a lower surface, wherein the first protrusion of the anti-slip plate is coupled to the groove of the upper plate.

### CROSS-REFERENCE TO RELATED APPLICATION

This application is based on and claims priority under 35 U.S.C. § 119 to Korean Patent Application No. 10-2023-0145965, filed on Oct. 27, 2023, in the Korean Intellectual Property Office, the disclosure of which is incorporated by reference herein in its entirety.

### BACKGROUND

The disclosure relates to a spin chuck and a substrate processing apparatus including the spin chuck, and more specifically, to a spin chuck with improved reliability and a substrate processing apparatus including the spin chuck.

In general, as semiconductor devices are more dense, highly integrated, and efficient, circuit patterns are miniaturized. Contaminants (such as particles, organic contaminants, and metal contaminants) remaining on a substrate surface have a significant impact on device characteristics and production yields. Accordingly, a cleaning process of removing various contaminants attached to the substrate surface becomes very important in a semiconductor manufacturing process. A process of cleaning substrates is performed before and after each of semiconductor manufacturing processes.

In the present semiconductor manufacturing process, a cleaning method is divided into dry cleaning and wet cleaning. The wet cleaning includes a bath-type method, which removes contaminants by immersing substrates in a chemical solution to chemically dissolving the contaminants. The wet cleaning also includes a spin-type method, which removes contaminants by placing a substrate on a spin chuck and supplying a chemical solution to a surface of the substrate while rotating the substrate.

In the spin-type method, a substrate is fixed onto the spin chuck that may handle a single substrate. Chemical liquid or deionized water is supplied to the substrate through a spray nozzle while rotating the substrate. The chemical liquid or deionized water is spread over the entire surface of the substrate by centrifugal force, and thereby, the substrate is cleaned, and then, the substrate is dried with dry gas.

### SUMMARY

Provided are a spin chuck that prevents slip due to rotation between an upper plate and a lower plate, and that prevents cracks caused by movement of a chucking pin, and a substrate processing apparatus including the spin chuck.

Aspects of the disclosure are not limited to the aspects described above. Other objects may be clearly understood by those skilled in the art from the description below.

According to an aspect of the disclosure, a spin chuck includes: an upper plate having an upper surface and a lower surface, the upper plate including a groove and a support pin on the upper surface of the upper plate, wherein the support pin is configured to support a substrate; an anti-slip plate below the upper plate, the anti-slip plate having an upper surface and a lower surface, wherein the anti-slip plate includes a first protrusion protruding in a vertical direction from the upper surface of the anti-slip plate toward the upper plate; and a lower plate below the anti-slip plate, the lower plate including a chucking pin configured to fix the substrate, wherein the lower plate has an upper surface and a lower surface, wherein the first protrusion of the anti-slip plate is coupled to the groove of the upper plate.

According to another aspect of the disclosure, a substrate processing apparatus includes: a spin chuck configured to support a substrate and to rotate around an axis extending along a vertical direction; an inverter configured to load the substrate onto an upper surface of the spin chuck or unload the substrate from the upper surface of the spin chuck; and a first nozzle circuit configured to eject processing fluid toward the substrate on the upper surface of the spin chuck, wherein the spin chuck includes: an upper plate having an upper surface and a lower surface, the upper plate including a groove, wherein the substrate is on the upper surface of the upper plate; an anti-slip plate below the upper plate, the anti-slip plate having an upper surface and a lower surface, the anti-slip plate including: a first protrusion protruding in the vertical direction from the upper surface of the anti-slip plate toward the upper plate, and a ring wing; and a lower plate below the anti-slip plate, the lower plate including a chucking pin configured to fix the substrate, wherein the lower plate has an upper surface and a lower surface, and wherein the first protrusion of the anti-slip plate is coupled to the groove of the upper plate.

According to another aspect of the disclosure, a substrate processing apparatus includes: a spin chuck configured to support a substrate and to rotate around a first axis extending along about a vertical direction; an inverter configured to fix the substrate, the inverter including a hand configured to reverse the substrate 180 degrees and a support coupled to the hand and having a shape extending in the vertical direction; and

a first nozzle circuit including a nozzle configured to eject processing fluid toward the substrate on an upper surface of the spin chuck, a nozzle arm on which the nozzle is mounted, and a support rod configured to support the nozzle arm and to rotate around a second axis extending along the vertical direction, wherein the spin chuck includes: an upper plate having an upper surface and a lower surface, the upper plate including a groove, wherein a substrate is on the upper surface of the upper plate; an anti-slip plate below the upper plate, the anti-slip plate having an upper surface and a lower surface, the anti-slip plate including: a first protrusion protruding in the vertical direction from the upper surface of the anti-slip plate toward the upper plate, and a ring wing; and a lower plate below the anti-slip plate, the lower plate including a chucking pin configured to fix the substrate, wherein the lower plate has an upper surface and a lower surface, wherein the first protrusion of the anti-slip plate is coupled to the groove of the upper plate, wherein a vertically protruding pattern is on at least one of the upper surface and the lower surface of the anti-slip plate, wherein a diameter of the anti-slip plate is in a range of about 240 mm to about 300 mm, wherein a thickness of the ring wing in the vertical direction is in a range of about 1 mm to about 3 mm, wherein one side surface of the ring wing comes into contact with a side surface of the lower plate, and another side surface of the ring wing comes into contact with the chucking pin, and wherein a shape of the first protrusion is identical to a shape of the groove.

### BRIEF DESCRIPTION OF DRAWINGS

Embodiments of the disclosure will be more clearly understood from the following detailed description taken in conjunction with the accompanying drawings in which:

FIG. 1 is a schematic cross-sectional view illustrating a substrate processing apparatus according to an embodiment;

FIG. 2 is a schematic exploded view illustrating a spin chuck according to an embodiment;

FIG. 3 is a schematic perspective view illustrating an upper plate of FIG. 2;

FIGS. 4A and 4B are respectively a top view and a bottom view schematically illustrating an anti-slip plate of FIG. 2;

FIGS. 5A and 5B are schematic cross-sectional views illustrating a movement of a ring wing of an anti-slip plate of FIG. 2;

FIGS. 6A and 6B are schematic cross-sectional views illustrating a movement of a chucking pin; and

FIGS. 7A to 7D are schematic plan views illustrating a surface of an anti-slip plate of the disclosure.

### DETAILED DESCRIPTION

Hereinafter, embodiments of the disclosure will be described in detail with reference to the accompanying drawings. The same reference numerals are used for the same components in the drawings, and redundant descriptions thereof are omitted.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In addition, in the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

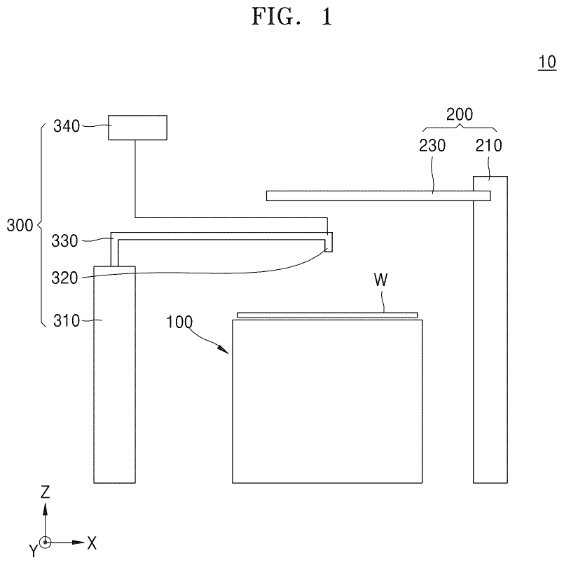

FIG. 1 is a schematic cross-sectional view illustrating a substrate processing apparatus according to an embodiment of the disclosure.

Referring to FIG. 1, a substrate processing apparatus 10 may include a spin chuck 100, an inverter 200, and a first nozzle circuit 300.

Hereinafter, the X-axis direction and the Y-axis direction in the drawings represent directions parallel to an upper or lower surface of the spin chuck 100, and the X-axis direction may be perpendicular to the Y-axis direction. The Z-axis direction may be perpendicular to the upper or lower surface of the spin chuck 100 and represent a rotation axis of the spin chuck 100. In the same sense, the Z-axis direction may be perpendicular to an X-Y plane (a plane having the X-axis direction and the Y-axis direction). The spin chuck 100 may support a substrate W and may be configured to rotate on the X-Y plane about the Z axis.

Also, in the drawings, a first horizontal direction may be referred to as the X-axis direction, a second horizontal direction may be referred to as the Y-axis direction, and a vertical direction may be referred to as the Z-axis direction.

The substrate W may be on the upper surface of the spin chuck 100, and the substrate W may be provided onto the upper surface of the spin chuck 100 by the inverter 200. The inverter 200 may include a support 210 extending in the vertical direction Z, and a hand 230. The inverter 200 may receive the substrate W delivered from outside the substrate processing apparatus 10. Specifically, the inverter 200 may receive the substrate W from the outside through the hand 230. In this case, the substrate W may be provided on an upper surface of the hand 230. Here, the upper surface of the hand 230 may be a surface in a direction opposite to the direction from which the hand 230 faces the spin chuck 100. The hand 230 may fix the substrate W. According to some embodiments, the hand 230 may fix the substrate W on the upper surface of the hand 230 by vacuum suction. Because the substrate W is provided on the upper surface of the hand 230, the substrate W may be in a direction opposite to the spin chuck 100.

The hand 230 may rotate such that the upper surface of the hand 230 and a lower surface of the hand 230, which is opposite to the upper surface, are reversed. After the substrate W is fixed on the upper surface of the hand 230, the inverter 200 may reverse the hand 230 such that the upper surface of the hand 230 faces the spin chuck 100. By reversing the hand 230, the substrate W may be arranged to face an upper surface of the spin chuck 100.

The support 210 may move the hand 230 in the vertical direction Z. The support 210 may have a shape extending in the vertical direction Z. The hand 230 may move downward in the vertical direction Z or upward in the vertical direction Z according to the direction in which the support 210 extends. The inverter 200 may cause the hand 230 to move downward in the vertical direction Z through the support 210 to provide the substrate W on the upper surface of the spin chuck 100.

In order to unload the substrate W from the spin chuck 100, the inverter 200 may fix the substrate W on the hand 230, and then, move the hand 230 upward in the vertical direction Z, and thereby, the substrate W may be unloaded.

The first nozzle circuit 300 may be configured to eject fluid onto an upper surface of the substrate W. The first nozzle circuit 300 may eject the fluid toward the substrate W on an upper surface of the spin chuck 100. The first nozzle circuit 300 may include a nozzle 320, a nozzle arm 330, a support rod 310, and a fluid supply 340. The nozzle 320 may receive processing fluid from the fluid supply 340. The nozzle 320 may eject the processing fluid onto an upper surface of the substrate W. The nozzle arm 330 may have a shape extending in one direction, and the nozzle 320 may be at a front end of the nozzle arm 330. According to some embodiments, the nozzle arm 330 may rotate in the X-Y plane about the vertical direction Z. In this case, the nozzle 320 coupled to the nozzle arm 330 may be moved together by rotation of the nozzle arm 330. The support rod 310 may be at a rear end of the nozzle arm 330. The support rod 310 may be below the nozzle arm 330. The support rod 310 may be perpendicular to the nozzle arm 330. According to some embodiments, a nozzle driver may be provided at a lower end of the support rod 310. The nozzle driver may rotate the support rod 310 on the X-Y plane about a longitudinal direction of the support rod 310, that is, the vertical direction Z. By rotation of the support rod 310, the nozzle arm 330 and the nozzle 320 may swing around the support rod 310. Accordingly, the nozzle 320 may eject the processing fluid while moving over a central region and an edge region of the substrate W.

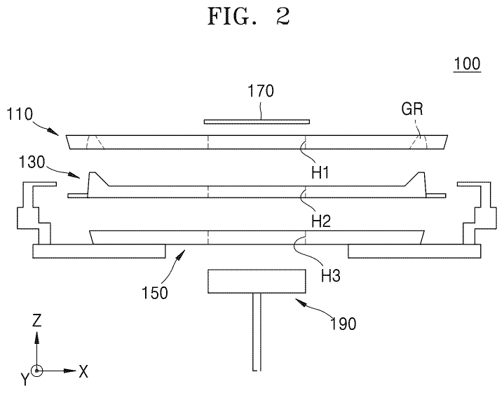

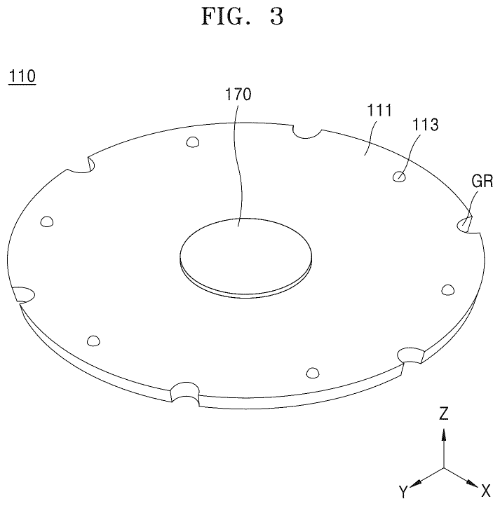

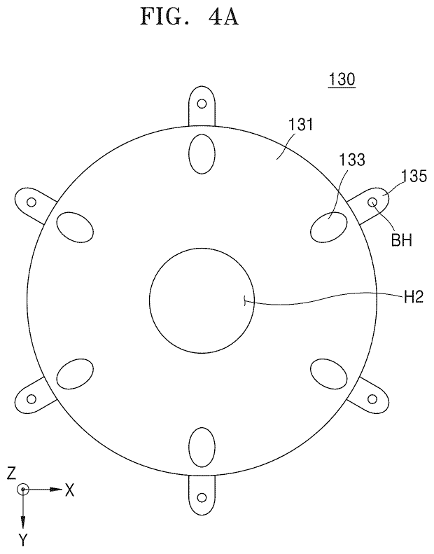

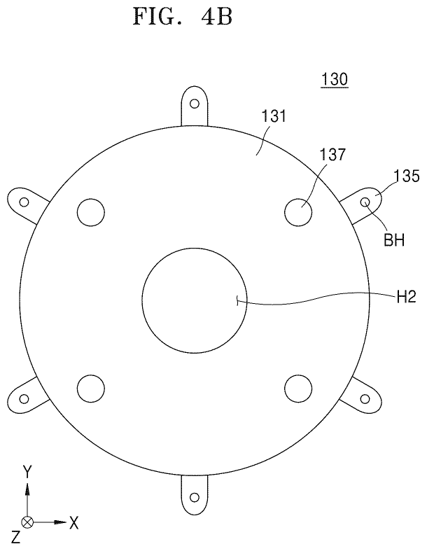

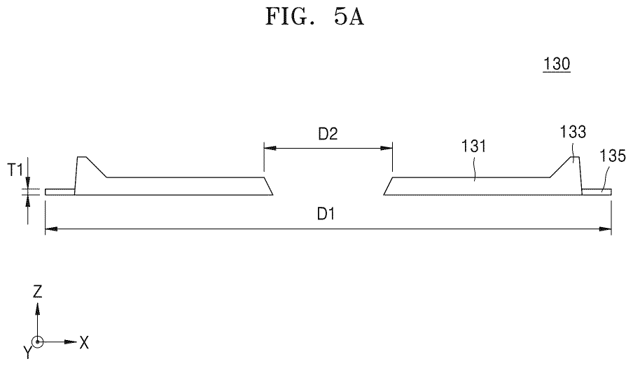

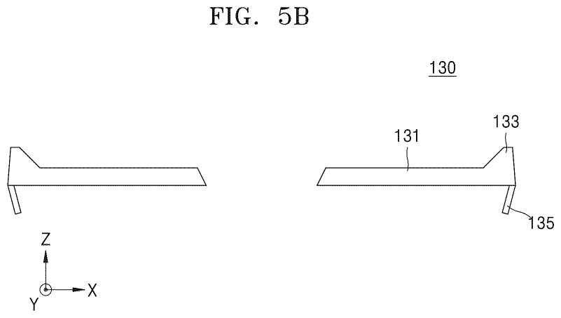

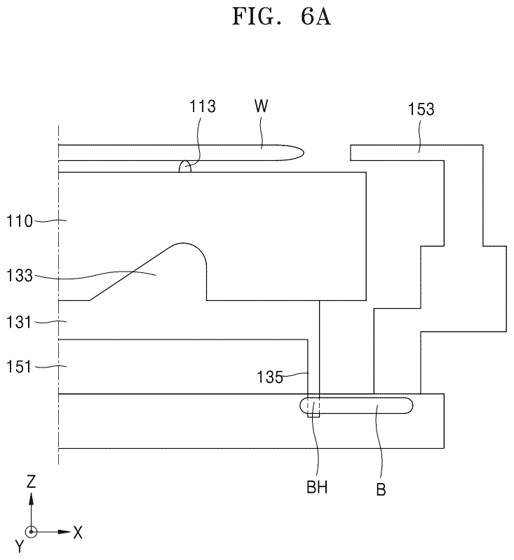

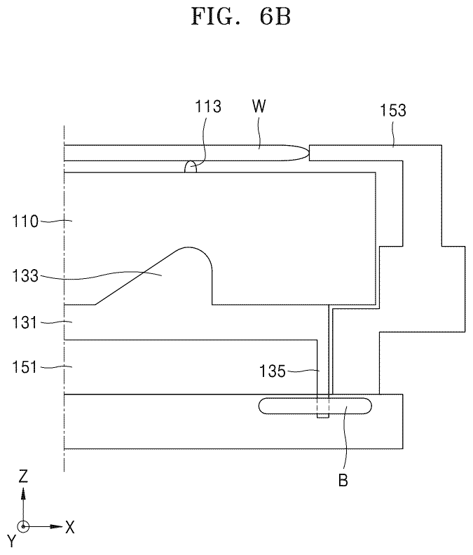

FIG. 2 is a schematic exploded view illustrating a spin chuck according to an embodiment. FIG. 3 is a schematic perspective view illustrating an upper plate of FIG. 2. FIGS. 4A and 4B are respectively a top view and a bottom view schematically illustrating an anti-slip plate of FIG. 2. FIGS. 5A and 5B are schematic cross-sectional views illustrating movement of a ring wing of the anti-slip plate of FIG. 2. FIGS. 6A and 6B are schematic cross-sectional views illustrating movement of a chucking pin.

Referring to FIGS. 2 to 6B, the spin chuck 100 may include an upper plate 110, an anti-slip plate 130, and a lower plate 150. In some embodiments, the spin chuck 100 may further include a second nozzle circuit 190.

The upper plate 110 may include a first body 111 (for example, as shown in FIG. 3) having an upper surface and a lower surface opposite to the upper surface, and a support pin 113 formed on the upper surface of the first body 111. At least one of the upper and lower surfaces of the first body 111 may be flat. According to some embodiments, the first body 111 may have a disk shape.

A groove GR (for example, as shown in FIG. 3) may be formed in a border region of the first body 111. A plurality of grooves GR may be formed to be arranged side by side at a preset distance along the border region of the first body 111. For example, as in FIG. 3, six grooves GR may be formed in a border region of the first body 111 when the six grooves GR are sequentially connected to each other by an imaginary line, i.e., the imaginary line may draw a regular hexagon. In the same sense, the six grooves GR may be arranged at vertices of a virtual regular hexagon around the center of the first body 111.

As shown in FIG. 3, the grooves GR may be formed in the outermost region of the first body 111. A groove shape may be formed in the border region of the first body 111 by the grooves GR. Grooves with the same number as the grooves GR formed in the first body 111 may be formed in the border region of the first body 111. According to some embodiments, the grooves GR may each have a semicircular shape when viewed from above in the vertical direction Z. However, embodiments of the disclosure are not limited thereto. For example, the grooves GR may have a polygonal shape when viewed from above in the vertical direction Z.

As shown in FIG. 3, the support pin 113 may be formed on an upper surface of the first body 111. In an embodiment, the support pin 113 may be configured to support a lower surface of the substrate W. The support pin 113 may be provided on an edge of an upper surface of the first body 111. A plurality of support pins 113 may be provided and may be arranged at preset intervals on the edge of the upper surface of the first body 111. The plurality of support pins 113 may protrude upward in the vertical direction Z from the upper surface of the first body 111. According to some embodiments, the plurality of support pins 113 may each have a cylindrical shape extending in the vertical direction Z.

According to some embodiments, the plurality of support pins 113 may be moved in the vertical direction Z. For example, the plurality of support pins 113 may switch between being arranged inside the first body 111 and protruding above the upper surface of the first body 111. When the plurality of support pins 113 are arranged inside the first body 111, vertical levels of upper surfaces of the plurality of support pins 113 may be equal to a vertical level of the upper surface of the first body 111, or may be lower than the vertical level of the upper surface of the body 111.

In some embodiments, a nozzle hole H1 (as shown in FIG. 2) may be formed in a central region of the first body 111. The second nozzle circuit 190 may be coupled to the first body 111 through the nozzle hole H1. The second nozzle circuit 190 may spray processing fluid on a lower surface of the substrate W. The second nozzle circuit 190 may include a spray portion for ejecting the processing fluid toward the lower surface of the substrate W, and a nozzle body. The spray portion may receive the processing fluid from a processing fluid supply portion within the nozzle body. The spray portion may spray the received processing fluid toward the lower surface of the substrate W.

The anti-slip plate 130 may be disposed below the upper plate 110. The anti-slip plate 130 may include a second body 131 and a ring wing 135, which are shown in FIG. 4. The second body 131 may have an upper surface and a lower surface that is opposite to the upper surface.

According to some embodiments, for example, as shown in FIG. 5A, a first protrusion 133 (protruding in the vertical direction Z) may be formed on an upper surface of the second body 131. The first protrusion 133 may protrude toward the upper plate 110 in the vertical direction Z from the upper surface of the second body 131. According to some embodiments, a plurality of first protrusions 133 may be provided. A number of first protrusions 133 may be equal to a number of the plurality of grooves GR formed in the upper plate 110. The plurality of first protrusions 133 may respectively overlap the plurality of grooves GR of the upper plate 110 in the vertical direction Z. According to some embodiments, each of the plurality of first protrusions 133 may be formed to have substantially the same shape as each of the plurality of grooves GR of the upper plate 110. The plurality of first protrusions 133 of the anti-slip plate 130 may be respectively inserted into the plurality of grooves GR of the upper plate 110. As the plurality of first protrusions 133 of the anti-slip plate 130 are respectively inserted into the plurality of grooves GR of the upper plate 110, the anti-slip plate 130 may be coupled to the upper plate 110. According to some embodiments, the plurality of first protrusions 133 may each be formed on a virtual straight line connecting the ring wing 135 to the center of the second body 131. That is, the center of the second body 131, the first protrusion 133, and the ring wing 135 may all be arranged on one straight line, which originates from the center of the second body 131 and extends to the right wing 135. A lower surface of the second body 131 may have a flat shape.

The second body 131 may have a higher friction coefficient than the first body 111 and a third body 151 (e.g., shown in FIG. 6A). According to some embodiments, the second body 131 may include at least one of silicon and urethane. When the second body 131 includes at least one of silicon and urethane, a slip between the second body 131 and the upper plate 110 and a slip between the second body 131 and the lower plate 150 may be prevented by a friction coefficient of silicon or urethane. In some embodiments, the second body 131 may include at least one of Teflon and Viton. The second body 131 including at least one of Teflon and Viton may have high heat resistance and chemical resistance. According to some embodiments, a diameter D1 (e.g., shown in FIG. 5A) of the second body 131 may be in a range of about 240 mm to about 300 mm.

In some embodiments, a nozzle hole H2 (e.g., shown in FIG. 4B) may be formed in a central region of the second body 131. The second nozzle circuit 190 may be coupled to the second body 131 through the nozzle hole H2. According to some embodiments, a diameter D2 (e.g., shown in FIG. 5A) of the nozzle hole H2 may be in a range of about 84 mm to about 92 mm.

In some embodiments, as shown in FIG. 4A, the ring wing 135 may be formed in a border region of the second body 131. The ring wing 135 may have a shape protruding outward from the border region of the second body 131. The ring wing 135 may have a semi-circular shape when viewed from above in the vertical direction Z. In some embodiments, as shown in FIG. 4A, a fastening hole BH may be formed in the center of the ring wing 135. According to some embodiments, a chucking pin 153 (e.g., as shown in FIG. 6A) may be coupled to the lower plate 150 by a bolt passing through the fastening hole BH. A thickness T1 of the ring wing 135 in the vertical direction Z may be in a range of about 1 mm to about 3 mm.

The ring wing 135 may be configured to switch between a state in which the ring wing 135 is parallel to the second body 131 in a horizontal direction, which is a longitudinal direction, as illustrated in FIGS. 4A, 4B, and 5A and a state in which the ring wing 135 is rotated downward in the vertical direction Z as illustrated in FIG. 5B. As the ring wing 135 rotates downward in the vertical direction Z, the ring wing 135 may come into contact with a side surface of the lower plate 150. The ring wing 135 may rotate to form a preset angle with the second body 131 in the vertical direction Z. However, in some embodiments, the ring wing 135 may be provided in a fixed state while forming a preset angle in the vertical direction Z with the second body 131 without being rotated.

The ring wing 135 may cover a region on the side surface of the lower plate 150 which overlaps the chucking pin 153 in the horizontal direction. That is, when the ring wing 135 comes into contact with the side surface of the lower plate 150, one side surface of the ring wing 135 comes into contact with the side surface of the lower plate 150, and another side surface opposite to the one side surface comes into contact with the chucking pin 153. According to some embodiments, the ring wing 135 may include silicon. According to some embodiments, the ring wing 135 may have a greater elastic modulus than the lower plate 150.

An adhesive member 137 may be on the lower surface of the second body 131. The adhesive member 137 may be between the lower surface of the second body 131 and an upper surface of the third body 151 of the lower plate 150. The second body 131 may be coupled to the third body 151 through the adhesive member 137. According to some embodiments, the adhesive member 137 may include pressure-sensitive adhesive. In a state where the adhesive member 137 includes a pressure-sensitive adhesive, when a vertical compressive stress is provided to couple the anti-slip plate 130 to the lower plate 150, the adhesive member 137 may bond the anti-slip plate 130 and the lower plate 150 together. In some embodiments, the adhesive member 137 may be provided in the form of an adhesive material and a capsule surrounding the adhesive material. In this case, when the vertical compressive stress is provided to couple the anti-slip plate 130 to the lower plate 150, the adhesive material in the capsule of the adhesive member 137 between the anti-slip plate 130 and the lower plate 150 may be provided outside the capsule, and accordingly, the anti-slip plate 130 and the lower plate 150 may be bonded together by the adhesive material.

The lower plate 150 may be below the anti-slip plate 130. The lower plate 150 may include the third body 151 and the chucking pin 153. The third body 151 may have an upper surface and a lower surface opposite to the upper surface. According to some embodiments, the third body 151 may have a disk shape.

In some embodiments, a nozzle hole H3 may be formed in a central region of the third body 151. The second nozzle circuit 190 may be coupled to the third body 151 through the nozzle hole H3.

The chucking pin 153 may be configured to fix a position of the substrate W as illustrated in FIGS. 6A and 6B. The chucking pin 153 may be on an edge side of the third body 151. A plurality of chucking pins 153 may be provided. According to some embodiments, the number of chucking pins 153 may be equal to the number of ring wings 135. According to some embodiments, the chucking pin 153 may include a body extending in the vertical direction Z and an arm extending in a direction perpendicular to the body. The chucking pin 153 may come into contact with the substrate W through the arm. According to some embodiments, the chucking pin 153 may fix the substrate W by coming into contact with the substrate W through the arm in a horizontal direction. The chucking pin 153 may come into contact with a side surface of the substrate W to fix the substrate W to the upper plate 110. The chucking pin 153 may include a fastening member B therein. The fastening member B may pass through the fastening hole BH formed in the ring wing 135 of the anti-slip plate 130 to couple the third body 151, the anti-slip plate 130, and the chucking pin 153 to each other.

As illustrated in FIG. 6A, when the substrate W is provided on an upper surface of the upper plate 110, the chucking pins 153 may be spaced apart from the substrate W in the first horizontal direction X. Thereafter, as illustrated in FIG. 6B, in order to fix the substrate W on the upper surface of the upper plate 110, the chucking pin 153 may move toward the substrate W in the first horizontal direction X and come into contact with the substrate W. As illustrated in FIGS. 6A and 6B, the chucking pin 153 may repeat movement in the first horizontal direction X to fix the substrate W.

The spin chuck 100 include an upper plate 110 and a lower plate 150, and the spin chuck 100 repeats high-speed rotation and low-speed rotation while rotating. Accordingly, a slip might occur between the upper plate 110 and the lower plate 150 due to repetition of the high-speed rotation and low-speed rotation, resulting in crack and damage in structurally weak portions of the upper plate 110 and the lower plate 150.

However, according to some embodiments of the disclosure, such slip may be prevented because the substrate processing apparatus 10 of disclosure includes the anti-slip plate 130 between the upper plate 110 and the lower plate 150 of the spin chuck 100. A friction coefficient of the anti-slip plate 130 is higher than friction coefficients of the upper plate 110 and the lower plate 150, and thus, even when the spin chuck 100 repeats high-speed rotation and low-speed rotation, the slip may be prevented from occurring between the upper plate 110 and lower plate 150. In addition, because the anti-slip plate 130 is inserted into the plurality of grooves GR formed in the upper plate 110 respectively through the plurality of first protrusions 133, a slip between the upper plate 110 and the anti-slip plate 130 may be prevented. Also, when the adhesive member 137 is provided on a lower surface of the anti-slip plate 130, a slip between the anti-slip plate 130 and the lower plate 150 may be prevented.

Furthermore, in some embodiments, the anti-slip plate 130 covers a region overlapping the chucking pin 153 in the horizontal direction on the lower plate 150 through the ring wing 135, and accordingly, even when the chucking pin 153 moves in the horizontal direction to fix the substrate W, the chucking pin 153 may not directly collide with the lower plate 150. Also, because an elastic modulus of the ring wing 135 is higher than an elastic modulus of the lower plate 150, the impact applied to the lower plate 150 by movement of the chucking pin 153 may be reduced.

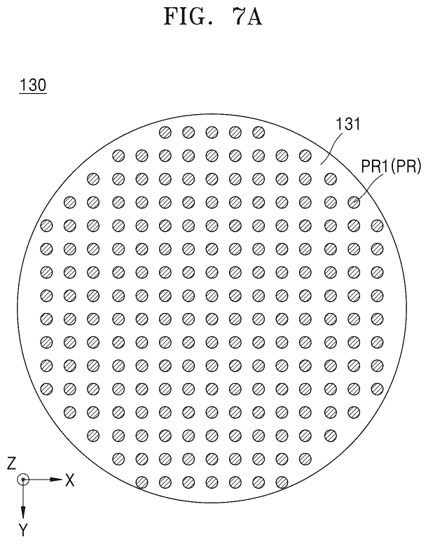

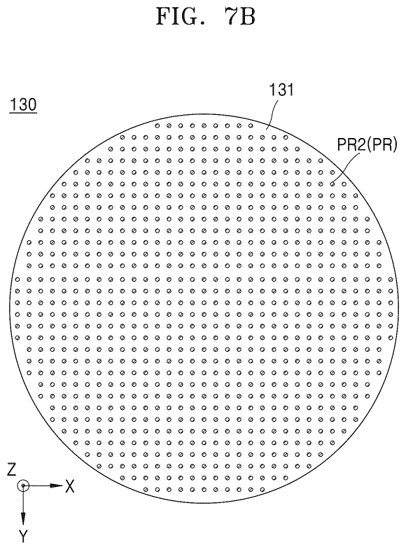

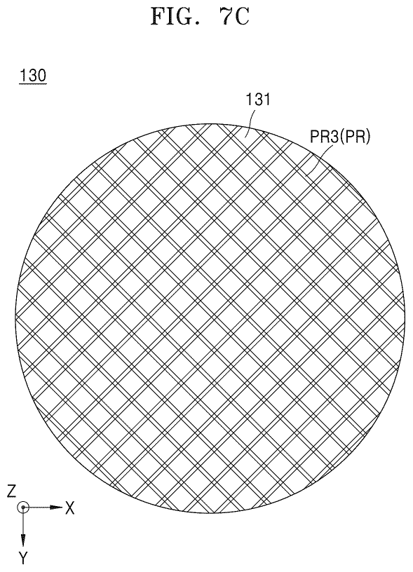

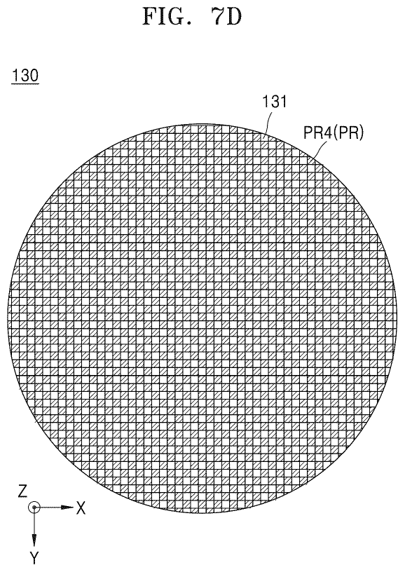

FIGS. 7A to 7D are schematic diagrams illustrating a surface of an anti-slip plate of the disclosure. In some embodiments, the anti-slip plate 130 may include the ring wing 135, the first protrusion 133, and the adhesive member 137. Patterns PR1, PR2, PR3, and PR4 illustrated in FIGS. 7A to 7D may represent at least one of upper and lower surfaces of the second body 131. Hereinafter, descriptions already made with reference to FIGS. 1 to 6B are omitted.

Referring to FIGS. 7A to 7D, the anti-slip plate 130 may include the second body 131. A pattern PR may be formed on at least one of the upper surface and the lower surface of the second body 131. That is, the pattern PR may be formed only on the upper surface of the second body 131, may be formed only on the lower surface of the second body 131, or may be formed on both the upper surface and the lower surface of the second body 131.

The pattern PR may be formed to protrude from a surface of the second body 131 in the vertical direction Z. A friction force between the second body 131 and an upper plate (110, see FIG. 2), or a friction force between the second body 131 and a lower plate (150, see FIG. 2) may further increase by the pattern PR formed on the second body 131.

According to some embodiments, as illustrated in FIG. 7A, the pattern PR may include or correspond to an embossing pattern PR1. The embossing pattern PR1 may protrude from the surface of the second body 131 in the vertical direction Z and may be a set of protrusions having a cylindrical shape. The embossing pattern PR1 (formed on the second body 131) may have a shape in which a plurality of cylinders protrude from the surface of the second body 131 in the vertical direction Z.

According to some embodiments, as illustrated in FIG. 7B, the pattern PR may include a spiny protrusion pattern PR2. The spiny protrusion pattern PR2 may protrude from the surface of the second body 131 in the vertical direction Z and may be a set of pillar-shaped protrusions of which horizontal cross-sectional area decreases as a vertical level increases. According to some embodiments, the spiny protrusion pattern PR2 may have a shape in which a plurality of cones protrude from the surface of the second body 131 in the vertical direction Z.

According to some embodiments, as illustrated in FIG. 7C, the pattern PR may include a mesh pattern PR3. The mesh pattern PR3 may protrude from the surface of the second body 131 in the vertical direction Z and may have a mesh shape when viewed from above in the vertical direction Z. The mesh pattern PR3 may have a narrower width or a wider width than the shape illustrated in FIG. 7C.

According to some embodiments, as illustrated in FIG. 7D, the pattern PR may include a check pattern PR4. The check pattern PR4 may protrude from the surface of the second body 131 in the vertical direction Z and may have a shape in which a plurality of squares are arranged in sequence when viewed from above in the vertical direction Z, and one of two adjacent rectangles may be a region protruding from the second body 131, and the other may be a region representing the surface of the second body 131.

As described above, embodiments are disclosed in the drawings and specification. In the disclosure, embodiments are described by using certain terms, but this is used only for the purpose of describing the disclosure and does not limit the meaning or scope of the disclosure described in the claims. Therefore, those skilled in the art will understand that various modifications and other equivalent embodiments may be derived therefrom.

While the disclosure has been particularly shown and described with reference to embodiments thereof, various changes in form and details may be made therein without departing from the spirit and scope of the following claims.

What is claimed is:

1. A spin chuck comprising:
an upper plate having an upper surface and a lower surface, the upper plate comprising a groove and a support pin on the upper surface of the upper plate, wherein the support pin is configured to support a substrate;
an anti-slip plate below the upper plate, the anti-slip plate having an upper surface and a lower surface, wherein the anti-slip plate comprises a first protrusion protruding in a vertical direction from the upper surface of the anti-slip plate toward the upper plate; and
a lower plate below the anti-slip plate, the lower plate comprising a chucking pin configured to fix the substrate, wherein the lower plate has an upper surface and a lower surface,
wherein the first protrusion of the anti-slip plate is coupled to the groove of the upper plate.

2. The spin chuck of claim 1, wherein the anti-slip plate further comprises a ring wing.

3. The spin chuck of claim 2, wherein the ring wing is configured to come into contact with a side surface of the lower plate, and
wherein the chucking pin is separated, in a horizontal direction, from the side surface of the lower plate with the ring wing therebetween.

4. The spin chuck of claim 3, wherein the ring wing is configured to switch between a state in which the ring wing is arranged in the horizontal direction and a state in which the ring wing is configured to cover the side surface of the lower plate.

5. The spin chuck of claim 1, wherein an adhesive member is on the lower surface of the anti-slip plate.

6. The spin chuck of claim 5, wherein the adhesive member comprises a pressure-sensitive adhesive.

7. The spin chuck of claim 1, wherein a vertically protruding pattern is on at least one of the upper surface of the anti-slip plate and the lower surface of the anti-slip plate.

8. The spin chuck of claim 1, wherein a shape of the first protrusion is identical to a shape of the groove.

9. The spin chuck of claim 1, wherein the anti-slip plate comprises at least one of silicone and urethane.

10. The spin chuck of claim 1, wherein the anti-slip plate comprises at least one of Teflon and Viton.

11. The spin chuck of claim 1, wherein a friction coefficient of the anti-slip plate is greater than a friction coefficient of the upper plate and a friction coefficient of the lower plate.

12. A substrate processing apparatus comprising:
a spin chuck configured to support a substrate and to rotate around an axis extending along a vertical direction;
an inverter configured to load the substrate onto an upper surface of the spin chuck or unload the substrate from the upper surface of the spin chuck; and
a first nozzle circuit configured to eject processing fluid toward the substrate on the upper surface of the spin chuck,
wherein the spin chuck comprises:
an upper plate having an upper surface and a lower surface, the upper plate comprising a groove, wherein the substrate is on the upper surface of the upper plate;
an anti-slip plate below the upper plate, the anti-slip plate having an upper surface and a lower surface, the anti-slip plate comprising:
a first protrusion protruding in the vertical direction from the upper surface of the anti-slip plate toward the upper plate, and
a ring wing; and
a lower plate below the anti-slip plate, the lower plate comprising a chucking pin configured to fix the substrate, wherein the lower plate has an upper surface and a lower surface, and
wherein the first protrusion of the anti-slip plate is coupled to the groove of the upper plate.

13. The substrate processing apparatus of claim 12, wherein a diameter of the anti-slip plate is in a range of about 240 mm to about 300 mm, and
wherein a thickness of the ring wing in the vertical direction is in a range of about 1 mm to about 3 mm.

14. The substrate processing apparatus of claim 12, wherein one side surface of the ring wing comes into contact with a side surface of the lower plate, and another side surface of the ring wing comes into contact with the chucking pin, and
wherein the ring wing comprises silicon.

15. The substrate processing apparatus of claim 12, wherein an adhesive member is between the anti-slip plate and the lower plate, and
wherein the adhesive member comprises an adhesive material and a capsule surrounding the adhesive material.

16. The substrate processing apparatus of claim 12, wherein a shape of the first protrusion is identical to a shape of the groove, and
wherein the first protrusion comprises six protrusion parts, and the groove comprises six groove parts.

17. The substrate processing apparatus of claim 12, wherein a friction coefficient of the anti-slip plate is greater than a friction coefficient of the upper plate and a friction coefficient of the lower plate, and
wherein an elastic modulus of the ring wing is greater than an elastic modulus of the lower plate.

18. A substrate processing apparatus comprising:
a spin chuck configured to support a substrate and to rotate around a first axis extending along about a vertical direction;
an inverter configured to fix the substrate, the inverter comprising a hand configured to reverse the substrate 180 degrees and a support coupled to the hand and having a shape extending in the vertical direction; and
a first nozzle circuit comprising a nozzle configured to eject processing fluid toward the substrate on an upper surface of the spin chuck, a nozzle arm on which the nozzle is mounted, and a support rod configured to support the nozzle arm and to rotate around a second axis extending along the vertical direction,
wherein the spin chuck comprises:
an upper plate having an upper surface and a lower surface, the upper plate comprising a groove, wherein a substrate is on the upper surface of the upper plate;
an anti-slip plate below the upper plate, the anti-slip plate having an upper surface and a lower surface, the anti-slip plate comprising:
a first protrusion protruding in the vertical direction from the upper surface of the anti-slip plate toward the upper plate, and
a ring wing; and
a lower plate below the anti-slip plate, the lower plate comprising a chucking pin configured to fix the substrate, wherein the lower plate has an upper surface and a lower surface,
wherein the first protrusion of the anti-slip plate is coupled to the groove of the upper plate,
wherein a vertically protruding pattern is on at least one of the upper surface and the lower surface of the anti-slip plate,
wherein a diameter of the anti-slip plate is in a range of about 240 mm to about 300 mm,
wherein a thickness of the ring wing in the vertical direction is in a range of about 1 mm to about 3 mm,
wherein one side surface of the ring wing comes into contact with a side surface of the lower plate, and another side surface of the ring wing comes into contact with the chucking pin, and
wherein a shape of the first protrusion is identical to a shape of the groove.

19. The substrate processing apparatus of claim 18, wherein the anti-slip plate comprises at least one of silicone and urethane.

20. The substrate processing apparatus of claim 18, wherein the vertically protruding pattern comprises an embossing pattern.
